(19) United States
(12) Patent Application Publication
(10) Pub. No.: US 2026/0081109 A1
(43) Pub. Date: Mar. 19, 2026

(54) POWER SUPPLY ASSEMBLY FOR GENERATING A PLASMA, AND PLASMA PROCESS SYSTEM

(71) Applicant: TRUMPF Hüttinger GmbH + Co. KG, Freiburg (DE)

(72) Inventor: Johannes Schlundt, Karlsruhe (DE)

(21) Appl. No.: 19/399,686

(22) Filed: Nov. 25, 2025

Related U.S. Application Data
(63) Continuation of application No. PCT/EP2024/064455, filed on May 24, 2024.

(30) Foreign Application Priority Data
May 26, 2023 (DE) 10 2023 113 990.8

(51) Int. Cl. H01J 37/32

(52) U.S. Cl. CPC H01J 37/32201; H01J 37/32266; H01J 37/32302; H01J 37/32311; H01J 37/32715; H01J 37/32889; H01J 2237/002

(57) ABSTRACT

A power supply assembly includes a plurality of microwave power supplies each designed to generate a microwave power signal for generating a plasma in a plasma process chamber, and a base including an upper face and a lower face. The microwave power supplies being arrangeable as an assembly on the upper face of the base. The base including plug contacts on the upper face, where the microwave power supplies include mating elements which match the plug contacts. The microwave power supplies being pluggable with the mating elements into the plug contacts of the base and being mechanically fastenable. At least one of the microwave power supplies being individually separable from the base while one or a plurality of the microwave power supplies are being operated. The base is designed to be attached with the lower face to a plasma process chamber upper face.

### CROSS REFERENCE TO RELATED APPLICATIONS

This application is a continuation of International Application No. PCT/EP2024/064455 (WO 2024/245970 A1), filed on May 24, 2024, and claims benefit to German Patent Application No. DE 10 2023 113 990.8, filed on May 26, 2023. The aforementioned applications are hereby incorporated by reference herein.

### FIELD

The present invention relates to a power supply assembly for generating a plasma in a plasma process chamber, and a plasma process system having a plasma process chamber, a plurality of applicators arranged in the plasma process chamber for coupling microwave power to generate the plasma, and a power supply assembly connected thereto.

### BACKGROUND

Such plasma process systems are known, for example, from the semiconductor industry for atom-level accurate material build-up, coating and/or etching. Products such as microprocessors, memory, power semiconductors, photovoltaic modules or displays are manufactured in this way. Typical arrangements are described, for example, in U.S. Pat. No. 10,971,413 B2 or U.S. Pat. No. 10,707,058 B2. These require a power supply assembly suitable for delivering microwave power to the applicators. Since a large number of applicators are often required, and these are arranged in geometrically very different configurations, the cabling of the power supply is often very complex, confusing, and prone to errors. If a power supply fails, the entire system often fails for an extended period of time, which can cause very high costs, in particular in the production of the aforementioned products.

### SUMMARY

In an embodiment, the present disclosure provides a power supply assembly that includes a plurality of microwave power supplies each designed to generate a microwave power signal including a power greater than or equal to 100 W and a frequency greater than or equal to 300 MHz for generating a plasma in a plasma process chamber, and a base including an upper face and a lower face. The microwave power supplies being arrangeable as an assembly on the upper face of the base. The base including plug contacts on the upper face, where the microwave power supplies include mating elements which match the plug contacts. The microwave power supplies being pluggable with the mating elements into the plug contacts of the base and being mechanically fastenable. At least one of the microwave power supplies being individually separable from the base while one or a plurality of the microwave power supplies are being operated. The base is designed to be attached with the lower face to a plasma process chamber upper face and to be mechanically adapted to the plasma process chamber in such a way that microwave power signals can be guided into the plasma process chamber via a plurality of applicators arranged on the plasma process chamber. The base is designed such that it can be connected to and separated from the plasma process chamber without the assembly of the microwave power supplies needed to be separated from the base.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1a, and FIG. 1b each show a power supply assembly;

FIG. 2a, and FIG. 2b each show a plasma process system;

FIG. 3 shows a detail area of the plasma process system with plug contacts;

FIG. 4 shows a detail area of the plasma process system with couplers in the base; and

FIG. 5, and FIG. 6 show a detail area of the plasma process system with splinters in the base.

### DETAILED DESCRIPTION

Embodiments of the present disclosure provide a power supply assembly and a plasma processing system that can be easily and quickly maintained.

A power supply assembly is therefore disclosed having:
a) a plurality of microwave power supplies, each designed to generate a microwave power signal with a power≥100 W and a frequency≥300 MHz for generating a plasma in a plasma process chamber,
b) a base with an upper face and a lower face, wherein the base is in particular designed so that the upper face can be arranged to be facing away from the plasma process chamber and the lower face can be arranged to be facing the plasma process chamber,
c) wherein the microwave power supplies can be, and in particular are, arranged as an assembly on the upper face of the base,
d) wherein the base has plug contacts on the upper face thereof,
e) wherein the microwave power supplies have mating elements which match the plug contacts,
f) wherein the mating plug elements of the microwave power supplies can be, and in particular also are, plugged onto the plug contacts of the base and mechanically secured,
g) wherein one, in particular a plurality, of the microwave power supplies can be separated from the base from the base, and in particular while these and/or one or a plurality of others are being operated,
h) wherein the base is designed to be attached with the lower face thereof to a plasma process chamber upper face and is mechanically adapted to the plasma process chamber in such a way that the microwave power signals can be guided into the plasma process chamber via a plurality of applicators arranged on the plasma process chamber,
i) wherein the base is designed in such a way that it can be connected to and separated from the plasma process chamber without needing to separate the assembly of microwave power supplies from the base.

This allows the microwave power supplies to be replaced quickly and easily, both individually and in combination with the base. The base need not necessarily be flat. It can also be curved, e.g., convexly or concavely curved. It can also take other forms. It is designed to be attached to the plasma process chamber and to be detachable therefrom. Therefore, it will generally be designed differently for different plasma process chambers. Additionally, the terms: the ‘upper face’ and ‘lower face’ of the base should not be interpreted in such a way to mean that the upper face must always be horizontal and oriented towards the sky, or the lower face must always be horizontal and oriented towards the earth. The orientation should instead be defined based on the plasma chamber, with the base designed so that the upper face faces away from the plasma process chamber and the lower face faces the plasma process chamber. However, it is often the case that the upper face is the side that points horizontally upwards and the lower face is also horizontally downwards.

Microwave power supplies can be designed as semiconductor-based power amplifiers, also known as solid-state power amplifiers (SSPA) or solid-state power generators (SSPG). Unlike magnetron arrays and/or tube amplifiers, semiconductor-based power amplifiers have the advantage of being highly efficient, small and compact, and therefore particularly well suited for this power supply assembly. At the same time, frequency, phase, pulse duration and output power can be adjusted particularly well and precisely. This applies in particular to a plurality of SSPGs individually as well as synchronized for groups of SSPGs, in particular for all of them.

In one aspect, the power supply assembly has a housing suitable for enclosing the array of microwave power supplies.

This protects the assembly of microwave power supplies from environmental influences and from unintentional interference by operators. At the same time, such a housing can also serve as shielding for electric and/or electromagnetic fields.

In one aspect, the power supply assembly features a control system designed to control the microwave power supplies.

The control system can be integrated into one of the microwave power supplies. This makes the power supply assembly even more compact and easier to maintain.

The control system can also be located outside the microwave power supplies, but inside the housing.

The control system can also be divided in such a way that a plurality of, in particular all, individual SSPGs have their own control system. This can then automatically take care of the individual regulation. In this process, a higher-level SSPG group control system can take over hierarchically superior functions or control individual SSPGs as needed.

The individual control systems can thus continue to function even without the group control systems in the event of a possible failure of the latter, thereby maintaining the process.

However, if an individual control system fails, only that SSPG fails and no other SSPGs will fail.

The control system can also be located outside the microwave power supplies and outside the housing.

In one aspect, one, in particular a plurality of, preferably all microwave power supplies have a communication port for connection to the control system.

In one aspect, the housing has one or a plurality of the following connections:
supply connection for connecting power supply, e.g., AC mains supply and/or DC power,
connections for communication, in particular digital communication, for connection to the control system and in particular a signal for synchronization,
cooling liquid connection.

This allows the connections to be disconnected before the housing is opened or removed, or before an SSPG is removed from the assembly.

In one aspect, the microwave power supplies are AFT-capable. ‘AFT-capable’ here refers to the property of automatically adjusting the output frequency of the microwave power according to predefined parameters. A given value could, for example, be a limit value for the reflected power. This allows for individual adjustments to power for a plurality of, and in particular all, power supplies.

AFT makes it possible to control the frequency in such a way that as much of the available microwave power as possible is coupled into the plasma process and as little as possible is reflected. Such an AFT-capable microwave power supply is described, for example, in patent application DE 10 2021 129 565 A1.

In one aspect, a plurality of, in particular all, microwave power supplies can be individually controlled in the frequency thereof. This allows for individual adjustments to power for a plurality of, and in particular all, power supplies. This can be achieved in particular through the control system, preferably through a central control system.

Therefore, an individual AFT by a plurality of, in particular all, SSPGs is possible, but an AFT for a group of SSPGs is also advantageous.

In one aspect, a plurality of, in particular all, microwave power supplies can be individually controlled in the power output thereof. This allows for individual power adjustment for a plurality of, in particular all, power supplies, thus influencing the power distribution and therefore the distribution of the plasma in the plasma process chamber. This can be achieved in particular through the control system, preferably through a central control system.

In one aspect, a plurality of, in particular all, microwave power supplies can be individually controlled in the phase thereof relative to another microwave power supply. This allows for individual power adjustment for a plurality of, in particular all, power supplies, thus influencing the power distribution and therefore the distribution of the plasma in the plasma process chamber. This can be achieved in particular through the control system, preferably through a central control system.

In one aspect, microwave power supplies are pulsable. Pulses can be set from ≥1 Hz to 20 MHz. The pulse-pause ratio can be set from 0% to 100%. Pulses can have different output powers. This allows for the implementation of multi-level pulses. Pulses can be provided as pulse packets, referred to as bursts. The pulses of individual microwave power supplies can be synchronized with each other. The pulses can also have a sequence. This allows for individual power adjustment for a plurality of, in particular all, power supplies, thus influencing the power distribution and therefore the distribution of the plasma in the plasma process chamber. This can be achieved in particular through the control system, preferably through a central control system.

In one aspect, the plug contacts of the base are designed to allow the connection of a microwave cable. This increases flexibility, and instead of installing a microwave power supply, microwave power from a remote microwave power supply can be introduced via a microwave line.

In one aspect, the plug contacts of the base have a protective device that protects the plug contacts when no mating plug element is connected. Such a protective device is described, for example, in patent application DE 10 2022 111 955 A1 disclosed as an ‘opening narrowing device’. The aforementioned application is hereby incorporated in its entirety into the present application by reference. Such a protective device reduces contamination when the microwave power supply is unplugged; this results in simplified handling when changing a microwave power supply. Furthermore, electromagnetic fields are reduced.

In one aspect, the power supply assembly is designed to supply microwave power to a microwave processing arrangement located on the process chamber side, e.g., an antenna array. An antenna array, in this context, refers to an arrangement with a plurality of applicators.

In one aspect, the base contains metal, in particular aluminum and/or copper. Preferably, it is made from one of these materials or a combination of a plurality of the aforementioned materials. This allows for good stability to be achieved. This also allows for good heat distribution.

In one aspect, one, in particular a plurality of, preferably all, microwave power supplies have a water connection for cooling liquid. This allows the microwave power supplies to be removed separately from the water.

In one aspect, the base has a cable guide. Thus, the plug contacts of the base do not need to be aligned with the applicators in the plasma chamber, but can be routed to a different location. This allows for more freedom in the arrangement of power supplies.

In one aspect, the base features a power combiner, also called a ‘combiner’ or ‘coupler’. This allows the power from a plurality of power supplies connected to this combiner to be directed to one applicator.

In one aspect, the base features a power divider, also referred to as a splitter. This allows the power from a power supply connected to this splitter to be directed to a plurality of applicators.

In one aspect, the base contains electronic components, e.g., inductors, capacitors, attenuators, and/or filters. This allows the construction method to be further simplified and made very compact.

Also disclosed is a plasma process system, having:
a) a plasma process chamber, preferably having a substrate carrier arranged therein for placing a substrate for processing with a plasma,
b) a plurality of applicators arranged in the process chamber for coupling microwave power to generate the plasma,
c) a power supply assembly as described above, connected to the applicators.

With such a plasma process system, microwave power supplies can be changed particularly quickly and easily, even during the operation of the plasma process, without needing to interrupt this operation.

The following drawings schematically show exemplary embodiments.

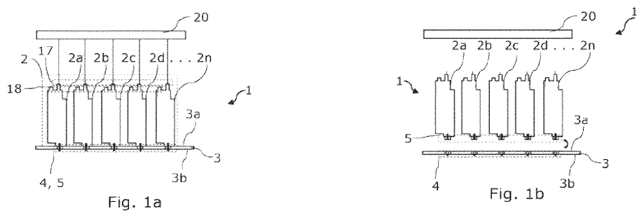

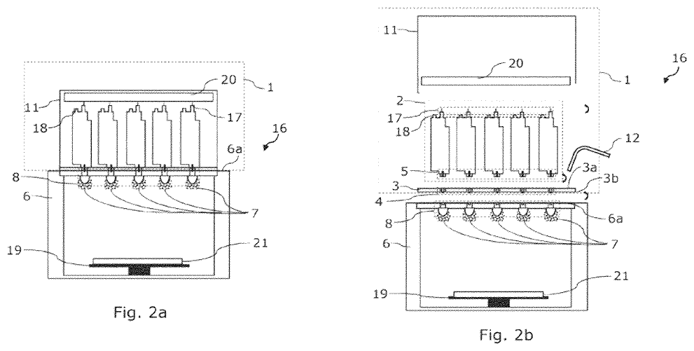

FIG. 1a shows a first embodiment of a power supply assembly 1. FIG. 1b shows the same embodiment of a power supply assembly 1 in an exploded view. FIGS. 2a and 2b show an embodiment of a plasma process system 16, each with a power supply assembly 1 and a plasma process chamber 6. The same reference symbols have been used for the same components. A plasma process system 16 has the following:
a plasma process chamber 6, preferably having a substrate carrier 19 arranged therein for placing a substrate 21 for processing with a plasma 7,
a plurality of applicators 8, arranged in the process chamber 6 for coupling microwave power to generate the plasma 7,
a power supply assembly 1, connected to the applicators 8.

The power supply assembly 1 includes: a plurality of microwave power supplies 2a, 2b, 2c, 2d, . . . 2n, each designed to generate a microwave power signal with a power≥100 W and a frequency≥300 MHz to generate a plasma 7 in a plasma process chamber 6. In the plasma process chamber 6 a substrate carrier 19 is arranged with a substrate 21 placed thereon. The substrate 21 is processed by the plasma during operation. Etching, coating, or surface modification can occur.

The power supply assembly 1 further has a base 3 with an upper face 3a and a lower face 3b. The base 3 is designed in such a way that the upper face 3a can be positioned facing away from the plasma chamber 6 and the lower face 3b can be positioned facing towards the plasma chamber 6. The base is flat here. However, this is not absolutely necessary, as already described above.

The microwave power supplies 2a, 2b, 2c, 2d, . . . 2n are arranged as an assembly 2 on the upper face 3a of the base 3.

The base 3 has plug contacts 4 on the upper face 3a thereof.

The microwave power supplies 2a, 2b, 2c, 2d, . . . 2n have mating elements 5 which match the plug contacts 4.

The microwave power supplies 2a, 2b, 2c, 2d, . . . 2n can be plugged with the mating plug elements 5 thereof onto the plug contacts 4 of the base 3 and mechanically fastened.

One, in particular a plurality, of the microwave power supplies 2a, 2b, 2c, 2d, . . . 2n can each be individually separated from the base 3, and in particular while these and/or one or a plurality of others are being operated, which is also called hot-plug capability.

The base 3 is designed here to be attached with the lower face 3b thereof to a plasma process chamber upper face 6a and to be mechanically adapted to the plasma process chamber 6 in such a way that the microwave power signals can be guided into the plasma process chamber 6 via a plurality of applicators 8 arranged on the plasma process chamber 6.

The base 3 is designed such that it can be connected to and separated from the plasma process chamber 6 without the assembly 2 of the microwave power supplies 2a, 2b, 2c, 2d, . . . 2n needing to be separated from the base 3.

The power supply assembly 1 in FIG. 2b has a housing 11 which is suitable for enclosing the assembly 2 of the microwave power supplies 2a, 2b, 2c, 2d, . . . 2n.

The power supply assembly 1 has a control system 20. This can be arranged with the microwave power supplies 2a, 2b, 2c, 2d, . . . 2n inside the housing 11 or outside thereof. This control system 20 is set up to control the microwave power supplies 2a, 2b, 2c, 2d, . . . 2n. To this end, the microwave power supplies 2a, 2b, 2c, 2d, . . . 2n each have a communication port 17 for connection to the control system 20.

The plasma process chamber upper face 6a of a plasma process chamber 6 can be a cover of the plasma process chamber 6 which is attached firmly and in a vacuum-tight manner to the plasma process chamber 6. The base 3 is easily removable without causing the plasma chamber 6 to leak, i.e., without any pressure change in the plasma process chamber 6. The lower face 3b of the base 3 and the upper face 6a of the plasma process chamber therefore represent a quick coupling. Thus, the assembly 2 can be changed without needing to change the conditions, such as the vacuum, in the plasma process chamber 6.

The housing 11 can have one or a plurality of the following connections:
supply connection for connecting power supply, e.g., mains supply and/or DC power,
connections for communication to connect to the control system,
cooling liquid connection.

This allows the connections to be disconnected before the housing is opened or removed.

The plug contacts 4 of the base 3 can enable the connection of microwave lines 12.

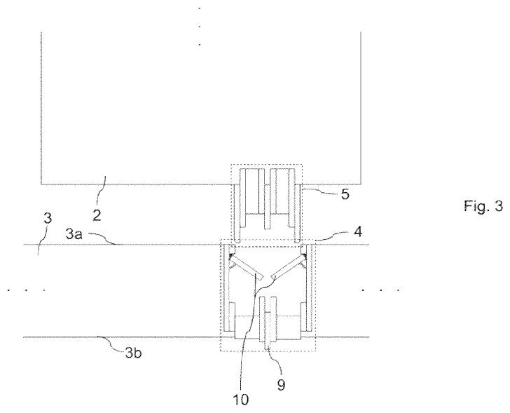

FIG. 3 shows a detailed view of the plug contacts 4 and the mating plug element 5. The plug contacts 4 of the base 3 can have a protective device 10 that protects the plug contacts 4 when no mating plug element 5 is connected.

One, in particular a plurality of, preferably all, microwave power supplies 2a, 2b, 2c, 2d, . . . 2n have a water connection 18 for cooling liquid.

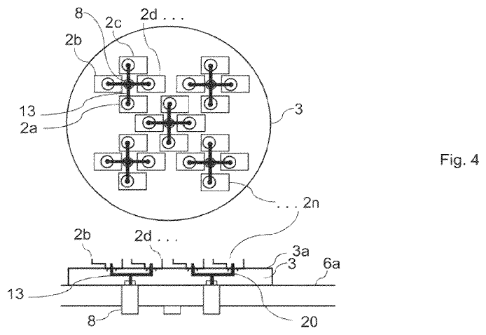

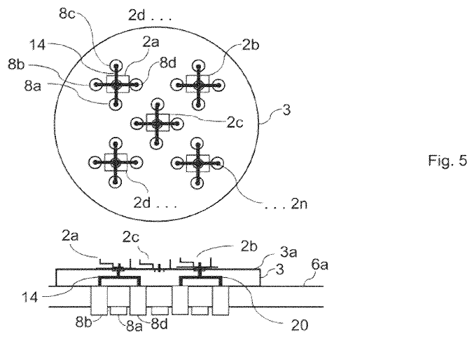

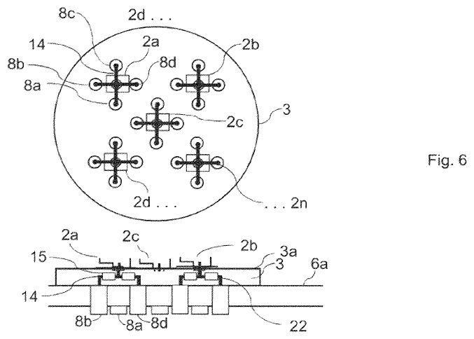

FIGS. 4, 5 and 6 show detailed areas of the plasma process system with combiners 13, splitters 14 or electronic components 15 in the base 3. The cable guides 22 in the base 3 are also shown.

Even though these cable guides 22 in the base 3 are only shown in arrangements together with combiners 13, splitters 14 or electronic components 15 in the base 3, this does not necessarily mean that these cable guides 22 can only be provided together with such components. A base 3 is also possible, in which a cable guide 22 is provided without a combiner 13, splitter 14, or electronic components 15.

The electronic components 15 can include, for example, inductors, capacitors, attenuators, delay lines, and/or filters.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A power supply assembly, comprising:
a) a plurality of microwave power supplies each designed to generate a microwave power signal comprising a power greater than or equal to 100 W and a frequency greater than or equal to 300 MHz for generating a plasma in a plasma process chamber,
b) a base comprising an upper face and a lower face,
c) the microwave power supplies being arrangeable as an assembly on the upper face of the base,
d) the base comprising plug contacts on the upper face,
e) the microwave power supplies comprising mating elements which match the plug contacts,
f) the microwave power supplies being pluggable with the mating elements into the plug contacts of the base and being mechanically fastenable,
g) at least one of the microwave power supplies being individually separable from the base while one or a plurality of the microwave power supplies are being operated,
h) the base being designed to be attached with the lower face to a plasma process chamber upper face and to be mechanically adapted to the plasma process chamber in such a way that microwave power signals can be guided into the plasma process chamber via a plurality of applicators arranged on the plasma process chamber, and
i) the base being designed such that it can be connected to and separated from the plasma process chamber without the assembly of the microwave power supplies needing to be separated from the base.

2. The power supply assembly according to claim 1, wherein the microwave power supplies are designed as semiconductor-based power amplifiers.

3. The power supply assembly according to claim 1, further comprising a housing for enclosing the assembly of the microwave power supplies.

4. The power supply assembly according to claim 3, wherein the housing has one or a plurality of the following connections:
supply connection for connecting power supply,
connections for communication for connecting to a control system, and/or
cooling liquid connection.

5. The power supply assembly according to claim 1, wherein the microwave power supplies are automatic frequency tuning (AFT)-capable.

6. The power supply assembly according to claim 1, wherein the power supply assembly further comprises a control system designed to control the microwave power supplies.

7. The power supply assembly according to claim 1, wherein the at least one of the microwave power supplies has a communication port for connecting with a control system.

8. The power supply assembly according to claim 1, wherein the plurality of microwave power supplies are individually controllable in the frequency.

9. The power supply assembly according to claim 1, wherein the plurality of microwave power supplies are individually controllable in the power.

10. The power supply assembly according to claim 1, wherein the plurality of microwave power supplies are pulsable, and wherein the pulses of individual microwave power supplies of the plurality of microwave power supplies can be synchronized to each other.

11. The power supply assembly according to claim 10, wherein the pulses can be set from greater than or equal to 1 Hz to 20 MHz and/or a pulse-pause ratio can be set from 0% to 100%.

12. The power supply assembly according to claim 1, wherein the plug contacts of the base have a protective device which protects the plug contacts when no mating plug element is connected.

13. The power supply assembly according to claim 1, wherein the base comprises one or more of a plurality of the following components:
cable guide,
combiner,
splitter, and/or
electronic components.

14. The power supply assembly according to claim 1, wherein the at least one of the microwave power supplies has a water connection for cooling liquid.

15. A plasma process system, comprising:
a) a plasma process chamber comprising a substrate carrier arranged therein for placing a substrate for processing with a plasma,
b) a plurality of applicators arranged in the process chamber for coupling microwave power to generate the plasma, and
c) a power supply assembly according to claim 1, connected to the plurality of applicators.
